(19) United States
(12) Patent Application Publication
(10) Pub. No.: US 2004/0250771 A1
(43) Pub. Date: Dec. 16, 2004

(54) Microwave plasma substrate processing device

(76) Inventors: Shigenori Ozaki, Amagasaki-Shi Hyogo (JP); Tamaki Yuasa, Amagasaki-Shi Hyogo (JP)

Correspondence Address: Crowell & Moring, PO Box 14300, Washington, DC, 20044-4300, US

(21) Appl. No.: 10/492,841

(22) PCT Filed: Oct. 17, 2002
(86) PCT No.: PCT/JP02/10798

(30) Foreign Application Priority Data
Oct. 19, 2001 (JP) 2001-322753

(51) Int. Cl. C23C 16/00

(52) U.S. Cl. 118/723 MW

(57) ABSTRACT

A microwave plasma substrate processing apparatus is formed of a processing vessel defining a process space in which a plasma processing is conducted, a stage provided in the process space for supporting the substrate to be processed, an evacuation passage formed between the processing vessel and the stage so as to surround the stage, an evacuation system connected to the processing vessel for evacuating the process space via the evacuation passage, a process gas supplying system for introducing a process gas into the process space, a microwave window provided so as to face the substrate to be processed on the stage and formed of a dielectric material and extending substantially parallel to the substrate to be processed, the microwave window forming a part of an outer wall of the processing vessel, and a microwave antenna coupled to the microwave window, wherein at least a part of the processing vessel is covered with an insulation layer.

### TECHNICAL FIELD

The present invention generally relates to substrate processing technology and more particularly to a substrate processing method of forming an insulation film on a silicon substrate.

In semiconductor production technology, formation of insulation film on a silicon substrate is a most fundamental and important technology. Especially, a particularly high quality insulation film is required for the gate insulation film of a MOS transistor or for the tunneling gate insulation film of a flash memory. Associated with this, there is a demand for the technology capable of forming such a thin insulation film with high quality.

### BACKGROUND ART

Conventionally, high-quality silicon oxide film for use in the gate insulation film of a MOS transistor has been formed by a thermal oxidation process of a silicon substrate surface. A silicon thermal oxide film thus formed contains small amount of dangling bonds, and thus, there occurs little trapping of carriers even in the case the film is used for the insulation film such as a gate insulation film that covers the channel region and exposed to a high electric field. Thereby, stable threshold characteristics can achieved.

Meanwhile, as a result of progress of miniaturization technology, production of ultrafine semiconductor devices having a gate length of less than 0.1 μm is becoming possible these days.

When to improve the device operational speed in such ultrafine semiconductor devices by way of reducing the gate length, there is a need of reducing the thickness of the gate insulation film according to scaling law. In the case of a MOS transistor having the gate length of 0.1 μm, for example, there is a need of decreasing the thickness of the gate insulation film to be 2 nm or less, while such a decrease of film thickness invites increase of gate leakage current by way of tunneling current in the case of a conventional thermal oxide film. From this, it has been considered that the film thickness of 2 nm would be the limit of gate insulation film formed by a thermal oxide film. In the thermal oxide film having the film thickness 2 nm, a gate leakage current of 1×10⁻² A/cm² is achieved.

On the other hand, there is a proposal of the technology that forms a higher quality silicon oxide film by way of oxidation processing by high-density microwave plasma.

FIG. 1 shows the construction of a substrate processing apparatus 10 that uses such high-density microwave plasma.

Referring to FIG. 1, the substrate processing apparatus 10 is constructed basically from an upper processing vessel 11 and a lower processing vessel 12 stacked with each other to define a process space 11A, a susceptor 13 provided in the process space 11A for holding a substrate W to be processed, and an alumina cover plate 14 functioning as a microwave window provided so as to close an upper part opening of the process space 11A. Further, there is formed a substrate transportation opening 11B between the upper and lower processing vessels 11 and 12 for loading and unloading the substrate W to be processed.

Around the susceptor 13, there is formed an evacuation passage surrounding the susceptor 13, and the process space 11A is evacuated via the evacuation passage by connecting an evacuation system to an evacuation opening 12A provided to a lower part of the processing vessel 12. In order to facilitate uniform evacuation of the process space 11A via the evacuation opening 12A, there is formed a rectification board 13A having a number of openings in the evacuation passage that surrounds the susceptor 13.

Further, the upper processing vessel 11 is subjected to temperature control by a thermal conductive medium passed through a passage 11D, and the upper processing vessel 11 is formed with a passage 11C of a process gas introduced to the process space 11A.

In such a substrate processing apparatus 10, a microwave antenna (not shown) such as a radial line slot antenna or horn antenna is connected to the microwave window 14. Thus, by introducing a rare gas such as Ar or Kr and an O₂ gas from the gas introduction port 11C and by driving the microwave antenna with a microwave of the frequency of several hundreds MHz to 10 GHz in this state, high-density plasma is formed in the processing vessel 11A with a uniform distribution on the surface of the substrate to be processed.

The rare gas plasma thus excited acts on the oxygen molecules introduced simultaneously, and as a result, atomic state oxygen O*is formed efficiently and uniformly in the process space 11A. By using such atomic state oxygen O* for the oxidation processing of a silicon substrate surface, it becomes possible to form a plasma oxide film having a film quality exceeding a thermal oxide film, which is formed at a temperature of 1000° C. or more, uniformly on the surface of the substrate to be processed at a low temperature of 600° C. or less.

In the substrate processing apparatus 10 of FIG. 1, the plasma is formed by a microwave of several hundred MHz to 10 GHz, and because of this, the plasma thus formed has the feature of not only high-density but also a low electron temperature. Thereby, there occurs no problem of sputtering of inner wall of the processing vessels 11 and 12, and the oxide film formed by the process is free from metal contamination originating from the processing vessel. Further, the oxide film thus obtained is free from damages caused by the microwave or plasma and has the preferable feature of reduced interface state density as compared with the case of a thermal oxide film.

In this way, the substrate processing apparatus 10 of FIG. 1 has the preferable feature of forming high quality oxide film at low temperatures. On the other hand, the inventor of the present invention has discovered, in the experiment constituting the foundation of the present invention, that the growth rate of the oxide film formed by the process is deteriorated as compared with the case of using other conventional high-density microwave plasma processing apparatus.

In the case of supplying a microwave of 2.45 GHz frequency with a power of 2000 W in the substrate processing apparatus 10 together with an Ar gas with a flow rate of 1000 SCCM and an oxygen gas with a flow rate of 20 SCCM under the pressure of 133 Pa, an oxide film growth rate of 6 nm/6 minutes is obtained, while this oxide film growth rate does not increase even when the microwave power is increased. This means that there is a limitation in the oxide film growth rate. Further, this oxide film growth rate is inferior to the value obtained with other conventional high-density microwave plasma substrate processing apparatuses.

FIG. 2 is a diagram showing the film thickness of an oxide film obtained by oxidizing the surface of a Si substrate in the substrate processing apparatus 10 of FIG. 1 under the foregoing condition while using Al for the processing vessels 11 and 12 in comparison with the case of using a stainless steel for the substrate processing vessels 11 and 12.

Referring to FIG. 1, it can be seen that the film thickness of the oxide film obtained with the substrate processing of 6 minutes is about 6 nm in the case Al is used. Thus in this case, the growth rate of the oxide film is only about 1 nm/minute. Further, little improvement is achieved when stainless steel is used for the substrate processing vessels 11 and 12.

The fact that the growth rate of the oxide film does not increase with increase of the microwave power and hence the plasma density on the surface of the substrate W to be processed means that the density of the atomic state oxygen O* formed on the substrate surface does not increase with the plasma density. This therefore means that a part of the atomic state oxygen O* thus formed is consumed somewhere in the process space 11A without contributing to the oxidation of the substrate W to be processed.

In the fabrication process of semiconductor devices, particularly the fabrication process for those semiconductor devices having a floating gate electrode such as a flash memory or EEPROM, there is a need for the technology capable of forming a high-quality oxide film efficiently with a certain film thickness. Thus, there is a need in the substrate processing apparatus of FIG. 1 to suppress the consumption of the atomic state oxygen O* not contributing to the oxidation and to increase the growth rate of the oxide film or insulation film further.

### DISCLOSURE OF THE INVENTION

Accordingly, it is a general object of the present invention to provide a novel and useful substrate processing apparatus wherein the foregoing problems are eliminated.

Another and more specific object of the present invention is to provide a substrate processing apparatus having a microwave window facing parallel to a substrate to be processed and processing a surface of the substrate to be processed uniformly by high-density plasma formed right underneath the microwave window, wherein consumption of radicals exited by the microwave plasma is minimized for improvement of a substrate processing efficiency.

Another object of the present invention is to provide a microwave plasma substrate processing apparatus, characterized by:

a processing vessel, said processing vessel defining a process space in which a plasma processing is conducted;

a stage provided in said process space, said stage supporting said substrate to be processed;

an evacuation passage formed between said processing vessel and said stage so as to surround said stage;

an evacuation system connected to said processing vessel, said evacuation system evacuating said process space via said evacuation passage;

a process gas supplying system, said process gas supplying system introducing a process gas into said process space;

a microwave window provided so as to face said substrate to be processed on said stage, said microwave window being formed of a dielectric material and extending substantially parallel to said substrate to be processed, said microwave window forming a part of an outer wall of said processing vessel; and

a microwave antenna coupled to said microwave window,

at least a part of said processing vessel being covered with an insulation layer.

Another object of the present invention is to provide a microwave plasma substrate processing apparatus, characterized by:

a processing vessel, said processing vessel defining a process space in which a plasma processing is conducted;

a stage provided in said process space, said stage holding a substrate to be processed;

an evacuation passage formed between said processing vessel and said stage;

an evacuation system coupled to said processing vessel, said evacuation system evacuating said process space via said evacuation passage;

a process gas supplying system, said process gas supplying system introducing a process gas into said process space; and

a microwave antenna coupled to said processing vessel,

said processing vessel being formed of a quartz glass, said processing vessel forming a microwave window substantially parallel to said substrate to be processed in a part thereof facing said substrate to be processed, said microwave antenna being coupled to said microwave window.

Another object of the present invention is to provide a microwave plasma substrate processing apparatus, characterized by:

a stage, said state holding a substrate to be processed;

a first processing vessel formed so as to surround said stage;

a second processing vessel formed on said first processing vessel, said second processing vessel defining, together with said stage and said first processing vessel, a process space in which a plasma processing is conducted;

an evacuation passage formed between said stage and said first processing vessel;

an evacuation system coupled to said first processing vessel, said evacuation system evacuating said process space via said evacuation passage;

a process gas supplying system, said process gas supplying system introducing a processing gas to said process space; and

a micro antenna connected to said second processing vessel,

said second processing vessel being formed of a quartz glass and forming a microwave window substantially parallel to said substrate to be processed in a part thereof facing said substrate to be processed, said microwave antenna being connected to said microwave window.

According to the present invention, the problem of extinction of the oxygen radicals formed by the high-density plasma at the inner wall surface of the processing vessel 11 or on the exposed surface and further on the sidewall surface of the susceptor 13, is suppressed by forming an insulation film of preferably an aluminum fluoride film or a quartz liner on the inner wall surface of the processing vessel that defines the process space. Further, by changing the material of the microwave window 14 from alumina to quartz glass, reduction of alumina to Al by the high-density plasma is suppressed, and as a result, the extinction of the radicals by Al is suppressed. As a result, a very high radical density is secured on the surface of the substrate W to be processed in the microwave plasma substrate processing apparatus, and the film growth rate is improved.

### BRIEF DESCRIPTION OF THE DRAWINGS

FIG. 1 is a diagram showing the construction of a conventional microwave plasma substrate processing apparatus;

FIG. 2 is a diagram showing the problems in the conventional microwave plasma substrate processing apparatus;

FIG. 3 is a diagram showing the construction of a microwave plasma substrate processing apparatus according to a first embodiment of the present invention;

FIG. 4 is a diagram showing the effect of the microwave plasma processing apparatus of FIG. 3;

FIG. 5 is a diagram showing the construction of a microwave plasma substrate processing apparatus according to a second embodiment of the present invention;

FIG. 6 is a diagram showing a modification of the microwave plasma processing apparatus of FIG. 5; and

FIG. 7 is a diagram showing the construction of a microwave plasma substrate processing apparatus according to a third embodiment of the present invention.

### BEST MODE FOR IMPLEMENTING THE INVENTION

### First Embodiment

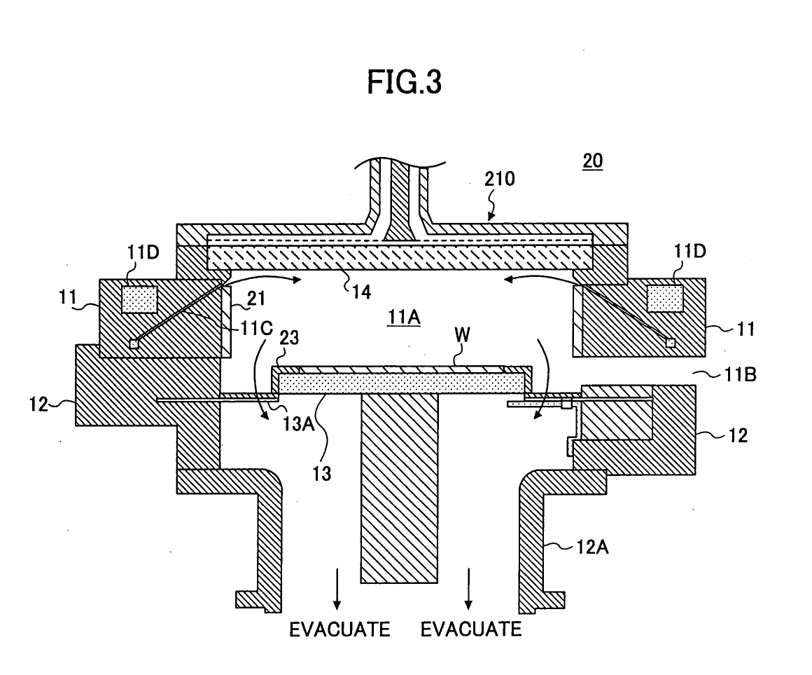

FIG. 3 shows the construction of a microwave plasma substrate processing apparatus 20 according to a first embodiment of the present invention, wherein those parts of FIG. 3 explained previously are designated by the same reference numerals and the description thereof will be omitted.

Referring to FIG. 3, the processing vessel 11 is formed of Al in the present embodiment and an aluminum fluoride layer 21 is formed on the inner wall surface thereof by a fluorinating processing. Further, the susceptor 13 is formed of AlN, and a quartz cover 23 is provided on the sidewall surface thereof and the surface exposed when the substrate W to be processed is mounted on the susceptor 13. In the construction of FIG. 3, a radial line slot antenna 210 is coupled to the microwave window 14 of alumina or a quartz glass, and a microwave supplied from an external microwave source is supplied to the processing space 11A through the microwave window 14.

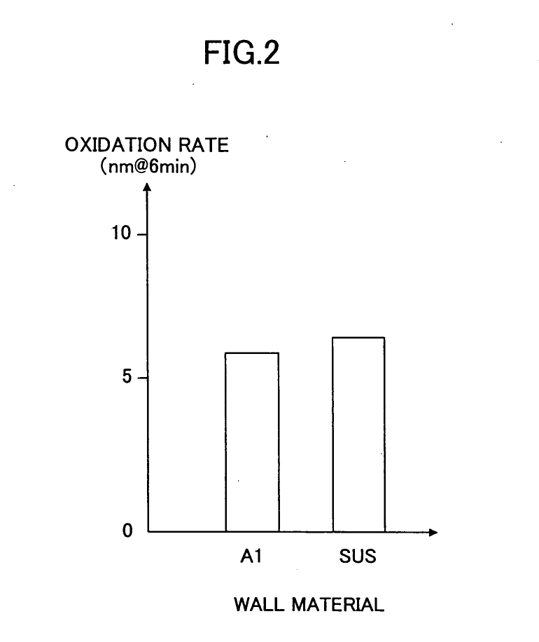

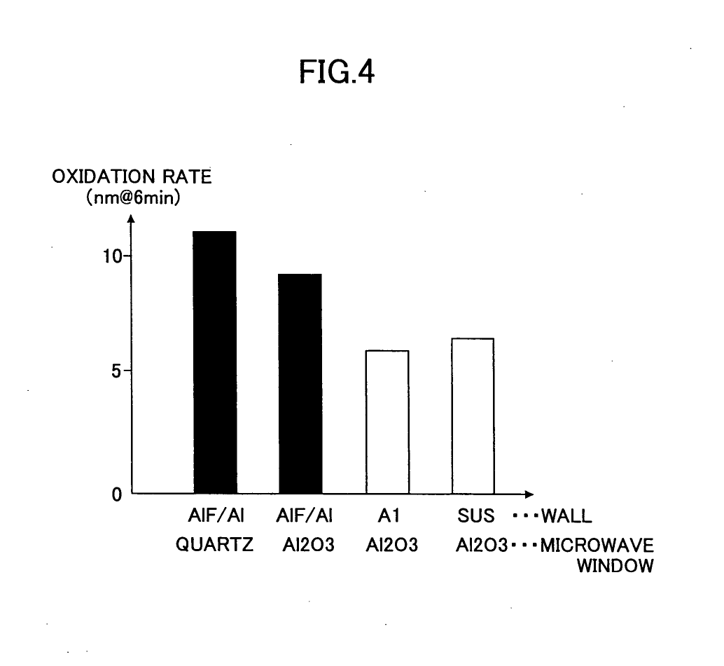

FIG. 4 shows the oxidation rate of the substrate W to be processed for the case the microwave plasma substrate processing 20 of FIG. 3 is operated under the same conduction explained previously with reference to FIG. 2 in comparison with the result of FIG. 2.

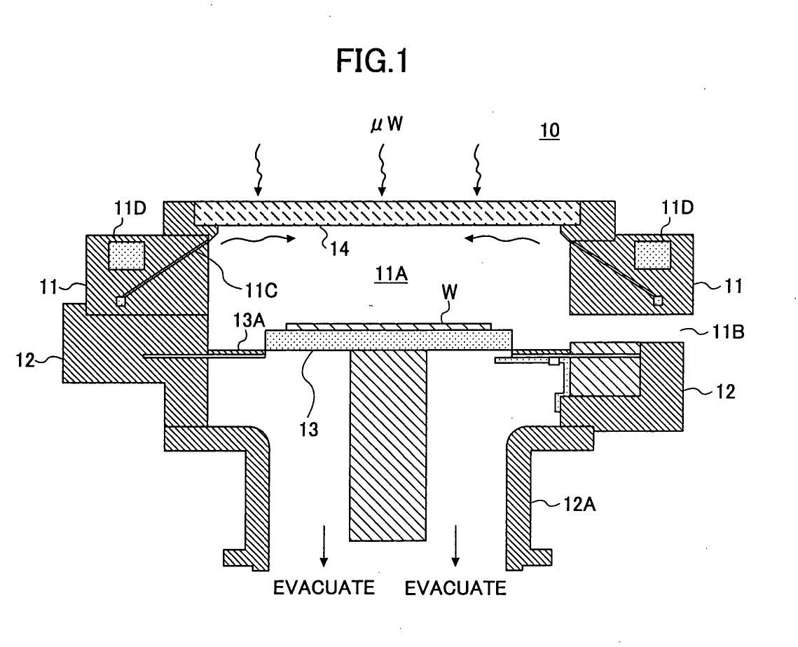

Referring to FIG. 4, it can be seen that the oxidation rate has increased by about 1.5 times as compared with the conventional oxidation rate as a result of formation of the aluminum fluoride layer on the inner surface of the processing vessel 11. This means that the microwave plasma substrate processing apparatus 20 can form a high-quality oxide film with a rate of 1.5 times as large as the conventional rate. Further, the result of FIG. 4 means that, in the microwave plasma substrate processing apparatus 10 of FIG. 1, substantial part of the atomic state oxygen O* formed in the process space 11A by the high-density plasma has been annihilated by the inner wall of the processing vessel 11.

Further, as shown in FIG. 4, it was discovered that the oxidation rate increased by about twice as compared with the conventional case by using a quartz glass for the microwave window 14 in place of alumina. This is interpreted that, in the case alumina is used for the microwave window 14, the alumina is reduced by the high-density plasma excited right underneath the microwave window 14, and it was this Al formed as a result of this has caused the extinction of the atomic state oxygen O*. In the case a quartz glass is used for the microwave window 14, there occurs no such a problem, and it is believed that this is the reason a large oxidation rate has been achieved in the case a quartz glass is used for the microwave window 14.

In the microwave plasma substrate processing apparatus 20 of FIG. 3, it is preferable to form the rectification board 13A provided in the evacuation passage surrounding the susceptor 13 by Al and form an aluminum fluoride layer on the surface thereof by a fluorinating process. Further, it is possible to use a quartz liner in place of the aluminum fluoride layer 21.

Further, it should be noted that the microwave plasma substrate processing apparatus 30 of the present embodiment is not only effective in oxidation processing of a silicon substrate but also in nitriding processing or oxynitriding processing thereof.

In the case of nitriding a silicon substrate, an NH₃ gas or an N₂ gas is introduced into the process space 11A together with a rare gas such as Ar or Kr. In the case of oxynitridation of a silicon substrate, an O2 gas may be added to the gas used for the nitriding processing.

### Second Embodiment

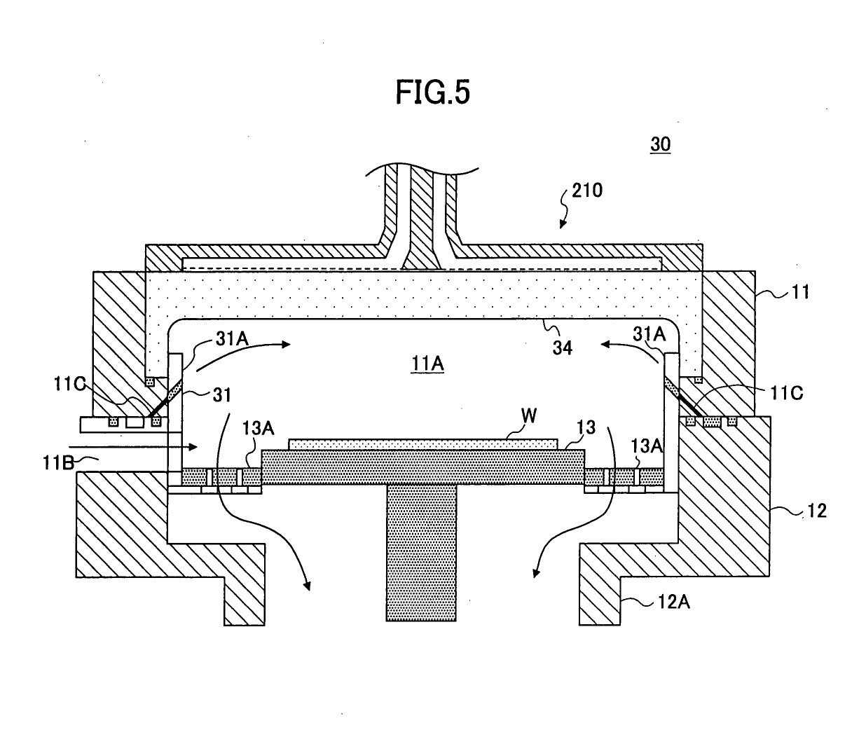

FIG. 5 shows the construction of a microwave plasma substrate processing apparatus 30 according to a second embodiment of the present invention.

Referring to FIG. 5, the microwave plasma substrate processing apparatus 30 is formed of the upper processing vessel 11 and the lower processing vessel similarly to the microwave plasma substrate processing apparatus 20 of the previous embodiment, except that there is provided a quartz glass vessel 34 of bell-jar form in place of the cover plate 14 so as to be held in the processing vessel 11, wherein the quartz vessel 34 is formed of a sidewall part engaging an inner wall surface of the processing vessel 11 and a ceiling part extending substantially parallel to the substrate W to be processed and defining the process space 11A together with the susceptor 13 and the rectification board 13A. Further, it should be noted that those parts of the processing vessel 11 not provided with the quartz vessel 34 is covered with a quartz liner 31, and the quartz liner 31 is provided with a process gas inlet port 31A communicating with the process gas passage 11C.

Further, the ceiling part of the quartz glass vessel 34 forms a microwave window, and the radial line slot antenna 210 is coupled to the microwave window as shown in FIG. 5.

In the microwave plasma processing apparatus 30 of such a construction, the inner wall surface of the process space 11A is covered with quartz glass, and annihilation of the atomic state oxygen O* at the metal inner wall surface is suppressed. Thereby, it becomes possible to conduct an oxidation processing with a rate corresponding to the supplied plasma power. As a result, it becomes possible to increase the oxide film formation rate significantly at the time of the oxidation processing as explained previously with reference to FIG. 4.

It should be noted that the microwave plasma substrate processing apparatus of the present embodiment is effective not only to the oxidation processing of the silicon substrate but also the nitriding processing or oxynitriding processing thereof.

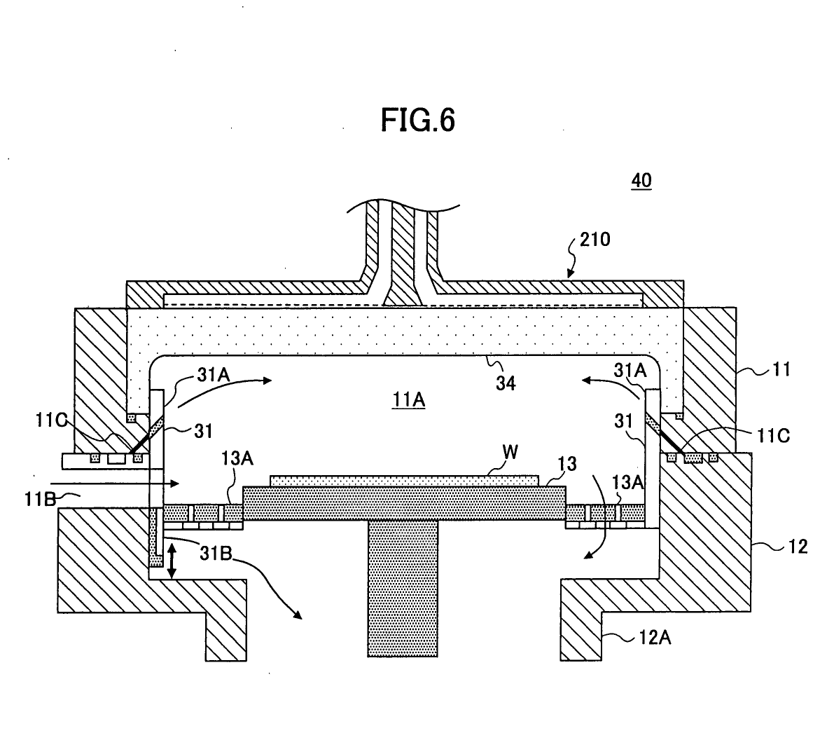

FIG. 6 shows the construction of a substrate processing apparatus 40 according to a modification of the microwave plasma substrate processing apparatus 30 of the present embodiment.

Referring to FIG. 6, a movable shutter 31B of quartz glass is formed at the substrate load/unload transportation opening 11B in the lower processing vessel 12. As a result, extinction of the atomic state oxygen O* at the substrate load/unload transportation opening 11B is suppressed, and the efficiency of substrate processing is improved further. Further, there occurs no decrease in the concentration of the atomic state oxygen O* in a particular direction of the substrate W to be processed, and a uniform substrate processing becomes possible in axial symmetry.

### Third Embodiment

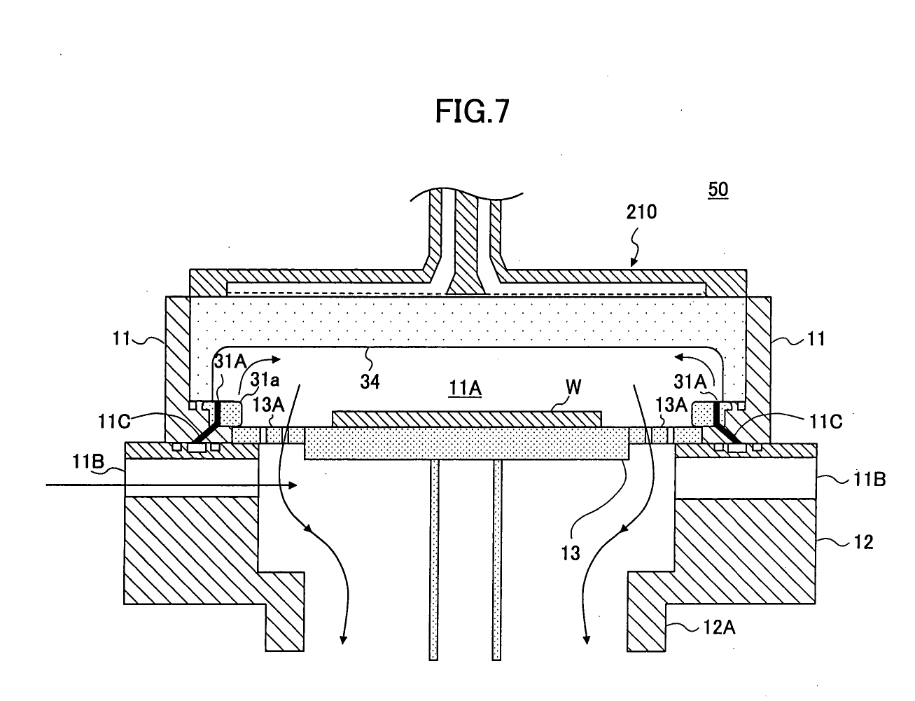

FIG. 7 is a diagram showing the construction of a microwave plasma substrate processing apparatus 50 according to a third embodiment of the present invention, wherein those parts corresponding to the parts described previously are designated by the same reference numerals and the description thereof will be omitted.

Referring to FIG. 7, the microwave plasma substrate processing apparatus 50 has the upper processing vessel 11 and the lower processing vessel 12 similarly to the substrate processing apparatus 30 or 40 of the previous embodiments, except that the susceptor 13 is constructed movable up and down, and the load/unload transportation opening 11B of the substrate W to be processed in formed in the lower vessel 12 in correspondence to the lowered position of the susceptor 13.

Further, the upper processing vessel 11 holds the quartz vessel 34 of bell-jar type explained before, wherein the process space 11A is formed inside the quartz vessel 34 in the state the susceptor 13 has moved up to a predetermined process position. Thereby, the processing vessel 11A is defined substantially by the inner wall surface of the quartz vessel 34 and the substrate W to be processed and held on the susceptor 13 and further by the rectifier board 13A formed in correspondence to the processing position of the susceptor 13.

In the construction of FIG. 7, there is further formed a ring 31a of quartz or Al having a surface subjected to fluorination processing between the quartz vessel 34 of the upper processing vessel 11 and the rectifier board 13A, wherein the gas inlet port 31A is formed in such a ring 31a in communication with the process gas passage 11C.

In the microwave plasma substrate processing apparatus 50 of such a construction, the process space 31A is substantially completely defined by a quartz glass or aluminum fluoride, and thus, there occurs excitation of high-density atomic state oxygen O* in correspondence to the plasma density in the case high-density plasma is formed in the process space 11A as a result of driving of the radial line slot antenna 210. By using such atomic state oxygen O*, it becomes possible to form a high-quality plasma oxide film efficiently.

Further, it should be noted that the microwave plasma substrate processing apparatus 50 of the present embodiment is effective not only for the oxidation processing of a silicon substrate but also in the nitriding processing or oxynitriding processing thereof.

Further, while a radial line slot antenna has been used for the microwave antenna in the foregoing explanation, the present invention is not limited to such a specific antenna construction, and it is also possible to use other microwave antennas such as a horn antenna.

Further, the present invention is not limited to the preferred embodiment described heretofore, but various variations and modifications may be made without departing from the scope of the invention described in the claims.

### INDUSTRIAL APPLICABILITY

According to the present invention, a processing rate corresponding to a plasma density is realized in a microwave plasma substrate processing apparatus that uses microwave plasma by covering an inner wall surface defining a processing space by an insulation film not annihilating excited radicals. Thereby, the efficiency of substrate processing is improved significantly.

1. A microwave plasma substrate processing apparatus, comprising:
a processing vessel, said processing vessel defining a process space in which a plasma processing is conducted;
a stage disposed in said process space, said stage supporting said substrate to be processed;
an evacuation passage formed between said processing vessel and said stage so as to surround said stage;
an evacuation system connected to said processing vessel, said evacuation system evacuating said process space via said evacuation passage;
a process gas supplying system, said process gas supplying system introducing a process gas into said process space;
a microwave window provided so as to face said substrate to be processed on said stage, said microwave window being formed of a dielectric material and extending substantially parallel to said substrate to be processed, said microwave window forming a part of an outer wall of said processing vessel; and
a microwave antenna coupled to said microwave window,
at least a part of said processing vessel being covered with an insulation layer.

2. The microwave plasma substrate processing apparatus as claimed in claim 1, wherein said process space is substantially defined by an insulation film.

3. The microwave plasma substrate processing apparatus as claimed in claim 1, wherein said processing vessel has an inner wall surface surrounding said substrate to be processed, said insulation layer covering said inner wall surface.

4. The microwave plasma substrate processing apparatus as claimed in claim 1, wherein said insulation layer comprises a layer of aluminum fluoride or SiO₂.

5. The microwave plasma substrate processing apparatus as claimed in claim 1, wherein said insulation film covers a peripheral edge part of a surface and a sidewall surface of said stage.

6. The microwave plasma substrate processing apparatus as claimed in claim 1, wherein said microwave window is formed of a quartz glass.

7. The microwave plasma substrate processing apparatus as claimed in claim 1, wherein said evacuation passage is provided with a rectification board, and wherein said rectification board is covered with a layer of aluminum fluoride or quartz glass.

8. The microwave plasma substrate processing apparatus as claimed in claim 7, in that wherein said rectification board defines said process space together with said processing vessel and said stage.

9. A microwave plasma substrate processing apparatus, comprising:
a processing vessel, said processing vessel defining a process space in which a plasma processing is conducted;
a stage disposed in said process space, said stage holding a substrate to be processed;
an evacuation passage formed between said processing vessel and said stage;
an evacuation system coupled to said processing vessel, said evacuation system evacuating said process space via said evacuation passage;
a process gas supplying system, said process gas supplying system introducing a process gas into said process space; and
a microwave antenna coupled to said processing vessel,
said processing vessel being formed of a quartz glass, said processing vessel forming a microwave window substantially parallel to said substrate to be processed in a part thereof facing said substrate to be processed, said microwave antenna being coupled to said microwave window.

10. The microwave plasma substrate processing apparatus as claimed in claim 9, wherein said evacuation passage is provided with a rectification board, wherein said rectification board is covered with a layer of aluminum fluoride or SiO₂.

11. The microwave plasma substrate processing apparatus as claimed in claim 10, wherein said stage is movable up and down between a process position in which a substrate is processed and a load/unload transportation position in which load/unload transportation of a substrate is conducted, said stage defining said process space in said processing position together with said processing vessel and said rectification board.

12. A microwave plasma substrate processing apparatus, comprising:
a stage, said stage holding a substrate to be processed;
a first processing vessel formed so as to surround said stage;
a second processing vessel formed on said first processing vessel, said second processing vessel defining, together with said stage and said first processing vessel, a process space in which a plasma processing is conducted;
an evacuation passage formed between said stage and said first processing vessel;
an evacuation system coupled to said first processing vessel, said evacuation system evacuating said process space via said evacuation passage;
a process gas supplying system, said process gas supplying system introducing a processing gas to said process space; and
a micro antenna connected to said second processing vessel,
said second processing vessel being formed of a quartz glass and forming a microwave window substantially parallel to said substrate to be processed in a part thereof facing said substrate to be processed, said microwave antenna being connected to said microwave window.

13. The microwave plasma substrate processing apparatus as claimed in claim 12, wherein said first processing vessel has an inner wall surface thereof covered by a liner of a quartz glass.

14. The microwave plasma substrate processing apparatus as claimed in claim 12, wherein said first processing vessel has an inner wall surface covered with an SiO₂ layer or an aluminum fluoride layer.

15. The microwave plasma substrate processing apparatus as claimed in claim 12, wherein said first processing vessel is formed with a load/unload transportation opening of a substrate to be processed, wherein said load/unload transportation opening is provided with a movable shutter covered with an aluminum fluoride layer or an SiO₂ layer.

16. The microwave plasma substrate processing apparatus as claimed in claim 12, wherein said second processing vessel comprises a sidewall part corresponding to said first processing vessel and a top part formed in continuation from said sidewall part in correspondence to said microwave window.

17. The microwave plasma substrate processing apparatus as claimed in claim 1, wherein said process gas supplying system supplies an oxygen gas to said processing vessel.

18. The microwave plasma substrate processing apparatus as claimed in claim 1, wherein said microwave processing apparatus processes a surface of said substrate to be processed by oxygen radicals.

19. The microwave plasma substrate processing apparatus as claimed in claim 12, wherein said process gas supplying system supplies an oxygen gas to said processing space.

20. The microwave plasma substrate processing apparatus as claimed in claim 12, wherein said microwave processing apparatus processes a surface of said substrate to be processed by oxygen radicals.
